(19) United States
(12) Patent Application Publication
(10) Pub. No.: US 2018/0182760 A1
(43) Pub. Date: Jun. 28, 2018

(54) DIELECTRIC STRUCTURE AND MANUFACTURING METHOD THEREOF AND MEMORY STRUCTURE

(71) Applicants: UNITED MICROELECTRONICS CORP., Hsin-Chu City (TW); Fujian Jinhua Integrated Circuit Co., Ltd., Jinjiang City (CN)

(72) Inventors: Ger-Pin Lin, Tainan City (TW); Tien-Chen Chan, Tainan City (TW); Shu-Yen Chan, Changhua County (TW)

(21) Appl. No.: 15/464,358

(22) Filed: Mar. 21, 2017

(30) Foreign Application Priority Data
Dec. 22, 2016 (CN) 201611198365.5

(51) Int. Cl. H01L 27/108; H01L 49/02; H01L 21/02

(52) U.S. Cl. CPC H01L 27/10814; H01L 28/40; H01L 21/02356; H01L 21/02175; H01L 27/10852

(57) ABSTRACT

A dielectric structure and a manufacturing method thereof and a memory structure are provided. The dielectric structure includes a dielectric layer and a plurality of crystalline grains disposed in the dielectric layer. The dielectric layer includes a first high-K dielectric material with a first dielectric constant. Each crystalline grain includes a second high-K dielectric material with a second dielectric constant greater than the first dielectric constant and greater than 20. Each crystalline grain has a crystal structure, so that each crystalline grain has a third dielectric constant greater than the second dielectric constant. Whole dielectric constant of the dielectric structure can be raised by performing an annealing process to form the crystalline grains in the dielectric layer, and the capacity of the memory structure for storing electric charges can be increased.

### BACKGROUND OF THE INVENTION

### 1. Field of the Invention

The present invention relates to a dielectric structure and a manufacturing method thereof and a memory structure, and more particularly to a dielectric structure including crystalline grains formed of a high-K dielectric material, and a manufacturing method thereof and a memory structure utilizing the dielectric structure.

### 2. Description of the Prior Art

In general, the unit structure of dynamic random access memory (DRAM) is composed of a transistor and a capacitor, and utilizes the capacitor for storing charge, so as to record the data. As the increase of the application, the size of DRAM needs to be shrunk constantly, so as to improve the aggressive of DRAM, accelerate the operating speed of the components, increase the capacity of DRAM and meet the consumer requirements miniaturizing the electrical devices.

However, when DRAM is shrunk, the size of the capacitor needs to be reduced also, such that the capacitance of the capacitor would be influenced, and it is more difficult to keep a certain amount of the capacitance. Regarding capacitance, the dielectric constant of the dielectric material in the capacitor is one of the key factors for determining the capacitance. In order to prevent the influence to the capacitance of the capacitor in the condition of reducing the size of component, to increase the dielectric constant of the dielectric material for reducing the thickness of the capacitor and providing the sufficient capacitance is an objective needed to be achieved constantly in this field.

### SUMMARY OF THE INVENTION

It is one of the objectives of the present invention to provide a dielectric structure and a manufacturing method thereof and a memory structure, so as to improve the whole dielectric constant of the dielectric structure and the capacity of the stored charge of the memory structure.

In order to achieve the above objective, the present invention provides a dielectric structure including a first dielectric layer and a plurality of first crystalline grains. The first dielectric layer includes a first high-K dielectric material, and the first high-K dielectric material has a first dielectric constant in an amorphous state. The first crystalline grains are disposed in the first dielectric layer. Each first crystalline grain includes a second high-K dielectric material, wherein each first crystalline grain has a crystal structure, so that a dielectric constant of each first crystalline grain is greater than a dielectric constant of the first high-K dielectric material and 20.

In order to achieve the above objective, the present invention provides a memory structure including a transistor, a bottom electrode, a top electrode and a dielectric structure. The transistor is disposed on a substrate. The bottom electrode is electrically connected to a source of the transistor. The top electrode is disposed on the bottom electrode. The dielectric structure is disposed between the bottom electrode and the top electrode, and the dielectric structure includes a first dielectric layer and a plurality of first crystalline grains. The first dielectric layer includes a first high-K dielectric material. The first crystalline grains are disposed in the first dielectric layer. Each first crystalline grain include a second high-K dielectric material, wherein each first crystalline grain has a crystal structure, so that a plurality of each first crystalline grain is greater than a dielectric constant of the first high-K dielectric material and 20.

In order to achieve the above objective, the present invention provides a manufacturing method of a dielectric structure, wherein the dielectric structure is formed on a bottom electrode. The manufacturing method of a dielectric structure includes the following steps. Firstly, an amorphous deposition layer is formed on the bottom electrode, and the amorphous deposition layer includes a first high-K dielectric material and a second high-K dielectric material, wherein the first high-K dielectric material and the second high-K dielectric material are mixed, and a second dielectric constant of the second high-K dielectric material is greater than a first dielectric constant of the first high-K dielectric material. Next, the amorphous deposition layer is performed an annealing process, so as to segregate the first high-K dielectric material and form a dielectric layer and a plurality of crystalline grains, and the crystalline grains are disposed in the dielectric layer, wherein the dielectric layer includes the first high-K dielectric material, and the dielectric layer includes the second high-K dielectric material.

In the manufacturing method of the dielectric structure of the present invention, the second amorphous grains can be crystallized effectively by performing the annealing process after forming the first amorphous grains and the second amorphous grains, thereby forming the crystal structure. Therefore, the dielectric constant of the amorphous second high-K dielectric material can be significantly increased to be the dielectric constant of the first crystalline grains so as to increase the dielectric constant of the whole dielectric structure. For this reason, the capacitance of the capacitor of the memory structure using the dielectric structure cannot be decreased in the condition of reducing the component area, and further, the capacitance of the capacitor can be increased even to increase the capacity of the stored charge.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing of a cross-sectional view of a capacitor structure according to a first embodiment of the present invention.

FIG. 2 is a schematic drawing of a flow chart of the manufacturing method of the dielectric structure according to the first embodiment of the present invention.

FIG. 3 is a schematic drawing of a cross-sectional view of the dielectric structure before the annealing process according to the first embodiment of the present invention.

FIG. 4 is a schematic drawing of a cross-sectional view of the manufacturing method of the dielectric structure according to a variant embodiment of the first embodiment of the present invention.

FIG. 5 is a schematic drawing of a cross-sectional view of the capacitor structure according to a second embodiment of the present invention.

FIG. 6 is a schematic drawing of a cross-sectional view of the capacitor structure according to a third embodiment of the present invention.

FIG. 7 is a schematic drawing of a block diagram of the memory structure according to an embodiment of the present invention.

### DETAILED DESCRIPTION

To provide a better understanding of the present invention to the skilled users in the technology of the present invention, preferred embodiments will be detailed as follows. The preferred embodiments of the present invention are illustrated in the accompanying drawings with numbered elements to elaborate on the contents and effects to be achieved.

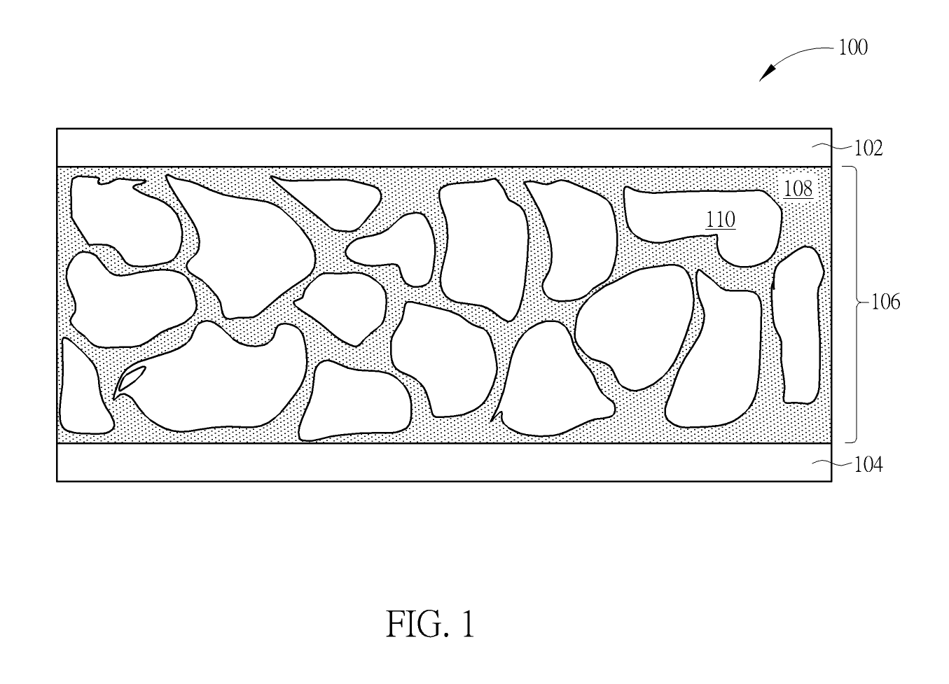

Please refer to FIG. 1, which is a schematic drawing of a cross-sectional view of a capacitor structure 100 according to a first embodiment of the present invention. As shown in FIG. 1, the capacitor structure 100 of this embodiment may include a top electrode 102, a bottom electrode 104 and a dielectric structure 106. The dielectric structure 106 is disposed between the top electrode 102 and the bottom electrode 104. And, the dielectric structure 106 includes a first dielectric layer 108 and a plurality of first crystalline grains 110. The first crystalline grains 110 are disposed in the first dielectric layer 108. Specifically, the first crystalline grains 110 may be embedded in the first dielectric layer 108. Wherein, the first dielectric layer 108 includes a first high-K dielectric material, each first crystalline grain 110 includes a second high-K dielectric material, and a dielectric constant of the second high-K dielectric material is greater than a dielectric constant of the first high-K dielectric material and 20. Particularly, because each first crystalline grain 110 may be formed by performing an annealing process to the second high-K dielectric material with high temperature, each first crystalline grain 110 may have a crystal structure respectively, such that a dielectric constant of each first crystalline grain 110 is greater than the dielectric constant of the amorphous second high-K dielectric material. Also, the first high-K dielectric material and the second high-K dielectric material are immiscible, such that they would not be mixed with each other in the annealing process.

Specifically, the first crystalline grains 110 may be separated each other by the first dielectric layer 108, so that the first crystalline grains 110 are not in contact with each other, thereby generating the discontinuous crystal structure. Since each first crystalline grain 110 has the crystal structure and the size of each first crystalline grain 110 is smaller than 100 nm, the defects of the first crystalline grains 110 would be increased, such that the dielectric constant is influenced by the space charge effect significantly. Thus, the dielectric constant of each first crystalline grain 110 can be increased to be greater than the dielectric constant of the amorphous second high-K dielectric material, thereby improving the dielectric constant of the whole dielectric structure 106. Preferably, the size of each first crystalline grain 110 may be bigger than 1 nm. The crystal structure of each first crystalline grain 110 may have different types according to the difference of the second high-K dielectric material, for example, each second high-K dielectric material may be zirconium oxide (ZrO₂), and the crystal structure of each first crystalline grain formed of the second high-K dielectric material may be cubic crystal structure, tetragonal crystal structure or monoclinic crystal structure. When the crystal structure of each first crystalline grain 110 is the cubic crystal structure, the dielectric constant of the first crystalline grains 110 can be 37. When the crystal structure of each first crystalline grain 110 is the tetragonal crystal structure, the dielectric constant of the first crystalline grains 110 can be 47 even. In another embodiment, the second high-K dielectric material may include hafnium oxide (HfO₂), lanthanum oxide (La₂O₃), cerium oxide (Ce₂O₃), barium titanate (BaTiO₃), gadolinium scandate (GdScO₃), dysprosium scandate (DyScO₃), lanthanum scandate (LaScO₃), lanthanum aluminate (LaAlO₃), lanthanum lutetium oxide (LaLuO₃), tantalum oxide (Ta₂O₅), titanium oxide (TiO₂) or strontium titanate (SrTiO₃), but not limited thereto.

In this embodiment, the dielectric structure 106 may be composed of the first dielectric layer 108 and a plurality of the first crystalline grains 110, and the first dielectric layer 108 is composed of the first high-K dielectric material, and the first crystalline grains 110 are composed of the second high-K dielectric material. Because the dielectric constant of the second high-K dielectric material is greater than the dielectric constant of the first high-K dielectric material, the volume of the first dielectric layer 108 is smaller than 45% of a total volume of the dielectric structure 106 to ensure that the dielectric constant of the dielectric structure 106 is high enough, that is to say, a ratio of the volume of the first crystalline grains 110 to the volume of the first dielectric layer 108 may be greater than 11/9. The first high-K dielectric material may be such as aluminum oxide (Al₂O₃) or silicon nitride (Si₃N₄), but the present invention is not limited thereto. The dielectric constant of the first high-K dielectric material may be greater than 20 preferably, such that the dielectric structure 106 may have the dielectric constant greater than 20. For example, the first high-K dielectric material may include zirconium oxide, hafnium oxide, lanthanum oxide, cerium oxide, barium titanate, gadolinium scandate, dysprosium scandate, lanthanum scandate, lanthanum aluminate, lanthanum lutetium oxide, tantalum oxide, titanium oxide or strontium titanate, in which the first high-K dielectric material should be different from the second high-K dielectric material. In another embodiment, the dielectric structure 106 may further include other high-K dielectric materials differing from the first high-K dielectric material and the second high-K dielectric material.

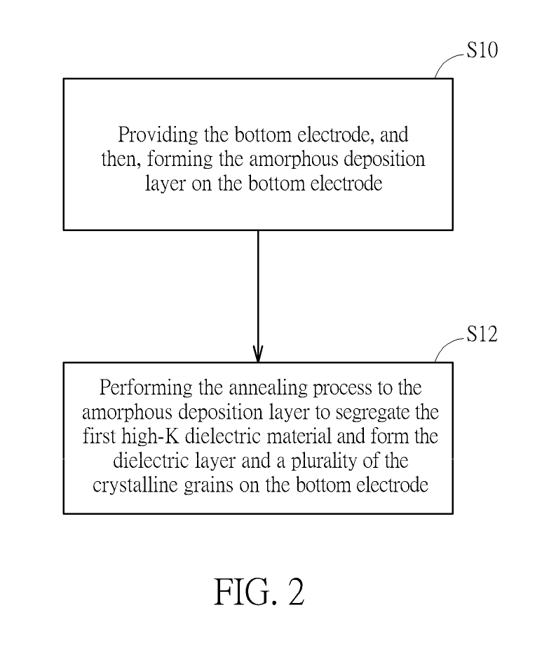

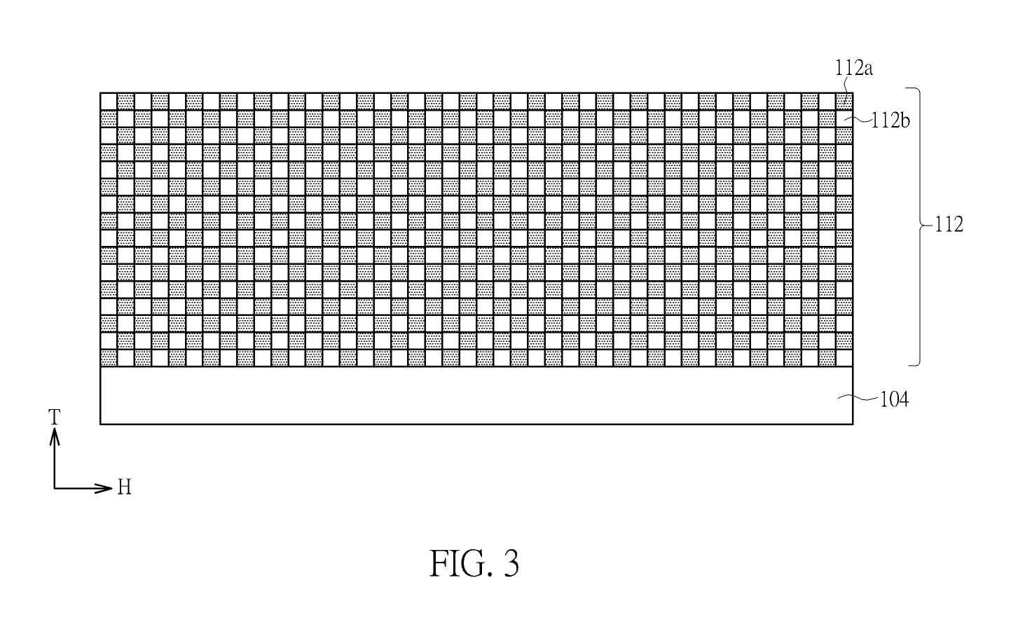

A manufacturing method of the dielectric structure 106 according to this embodiment will be detailed as follows. Please refer to FIG. 2 and FIG. 3 together with FIG. 1. FIG. 2 is a schematic drawing of a flow chart of the manufacturing method of the dielectric structure according to the first embodiment of the present invention. FIG. 3 is a schematic drawing of a cross-sectional view of the dielectric structure before the annealing process according to the first embodiment of the present invention. As shown in FIG. 2, the manufacturing method of the dielectric structure 106 according to the first embodiment may include the following steps. Firstly, the step S10 is performed to form an amorphous deposition layer 112 on the bottom electrode 104. The amorphous deposition layer 112 may include the first high-K dielectric material and the second high-K dielectric material, and the first high-K dielectric material and the second high-K dielectric material are mixed with each other. Specifically, the amorphous deposition layer 112 may include a plurality of first amorphous grains 112a and a plurality of second amorphous grains 112b, in which each first amorphous grain 112a includes the first high-K dielectric material, and each second amorphous grain 112b includes the second high-K dielectric material. The first amorphous grains 112a and the second amorphous grains 112b maybe disposed alternately in a thickness direction T, and the first amorphous grains 112a and the second amorphous grains 112b may be disposed alternately in a horizontal direction H also, so that the first amorphous grains 112a and the second amorphous grains 112b may be mixed in the amorphous deposition layer 112, as shown in FIG. 3.

In this embodiment, the method for forming the first amorphous grains 112a and the second amorphous grains 112b will be detailed as follows. Firstly, a first precursor of the first high-K dielectric material and a second precursor of the second high-K dielectric material may be introduced simultaneously. Then, a reactive gas able to react with the first precursor and the second precursor is introduced, so as to deposit and form the first high-K dielectric material mixing with the second high-K dielectric material. This step may be performed by the atomic layer deposition (ALD) process or the chemical vapor deposition (CVD) process, but not limited thereto. It should be noted that the first high-K dielectric material and the second high-K dielectric material of this embodiment may be formed by using the same reactive gas. For example, both the first high-K dielectric material and the second high-K dielectric material may be oxide, such as aluminum oxide and zirconium oxide respectively. The same reactive gas, such as ozone, may be utilized to react with the different precursors, so as to form aluminum oxide and zirconium oxide respectively, but not limited thereto.

Then, as shown in FIG. 1 and FIG. 2, the step S12 is performed to perform the annealing process to the amorphous deposition layer 112, so as to segregate the first high-K dielectric material and form the first dielectric layer 108 including the first high-K dielectric material and a plurality of the first crystalline grains 110 including the second high-K dielectric material on the bottom electrode 104. For example, the temperature of the annealing process may be about 350 to about 700° C. Because the first high-K dielectric material and the second high-K dielectric material are immiscible, the first dielectric layer 108 and the first crystalline grains 110 are not mixed each other in the annealing process. For example, when the first high-K dielectric material is aluminum oxide, the annealing process with high temperature would segregate the first amorphous grains 112a composed of the first high-K dielectric material to form the first dielectric layer 108 and gather the second amorphous grains 112b composed of the second high-K dielectric material and near each other to form the crystal structure, thereby generating the first crystalline grains 110. Particularly, in order to make the size of the first crystalline grains 110 smaller than 100 nm, the size of the second amorphous grains 112b formed in the step S10 is smaller than the size of the first crystalline grains 110. In this embodiment, after the annealing process, the top electrode 102 may be formed on the first dielectric layer 108, so as to form the capacitor structure 100. In another embodiment, the annealing process also may be performed after the formation of the top electrode 102 in the condition without affecting the top electrode 102.

In the manufacturing method of the dielectric structure 106 of this embodiment, the annealing process is performed after forming the first amorphous grains 112a and the second amorphous grains 112b, so that the second amorphous grains 112b can be crystallized effectively to form the crystal structure. Therefore, the dielectric constant of the amorphous second high-K dielectric material can be increased to be the dielectric constant of the first crystalline grains 110 significantly, so as to increase the dielectric constant of the whole dielectric structure 106.

In another embodiment, the first high-K dielectric material may be formed as the first dielectric layer 108 having the crystal structure by the annealing process, such that the dielectric constant of the crystallized first dielectric layer 108 may be greater than the dielectric constant of the amorphous first high-K dielectric material, thereby improving the dielectric constant of the whole dielectric structure 106.

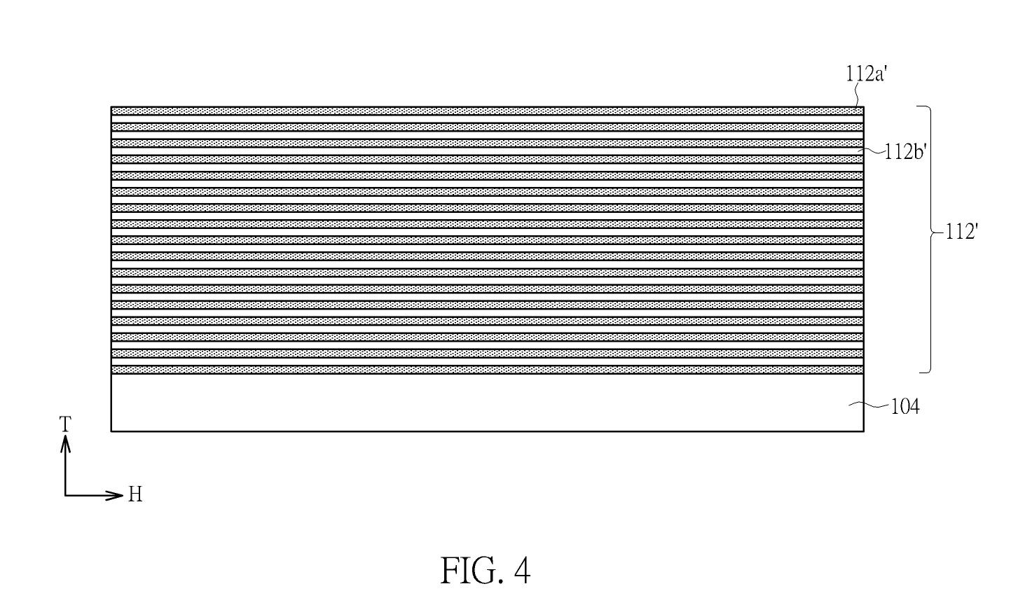

The manufacturing method of the dielectric structure according the present invention is not limited to the aforementioned embodiments. Please refer to FIG. 4, which is a schematic drawing of a cross-sectional view of the manufacturing method of the dielectric structure according to a variant embodiment of the first embodiment of the present invention. As shown in FIG. 4, the difference between this variant embodiment and the aforementioned embodiment is that the first amorphous grains including the first high-K dielectric material and the second amorphous grains including the second high-K dielectric material in the step S10 may be formed separated. Specifically, the amorphous deposition layer 112′ formed in the step S10 of this variant embodiment includes a plurality of first amorphous layers 112a′ and a plurality of second amorphous layers 112b′, in which each first amorphous layer 112a′ includes the first high-K dielectric material, and each second amorphous layer 112b′ includes the second high-K dielectric material. Also, the step S10 for forming the amorphous deposition layer 112′ includes alternately forming each first amorphous layer 112a′ and each the second amorphous layer 112b′ on the bottom electrode 104. That is to say, when the first high-K dielectric material formed of silicon nitride and the second high-K dielectric material formed of zirconium oxide are taken as an example, the deposition process of the first amorphous layers 112a′ of silicon nitride and the deposition process of the second amorphous layers 112b′ of zirconium oxide may be alternately performed, so as to alternately stack the first amorphous layers 112a′ and the second amorphous layers 112b′. Then, the annealing process in the step S12 is performed to form the first dielectric layer 108 and the first crystalline grains 110. Subsequently, the top electrode 102 is formed on the first dielectric layer 108, so as to form the capacitor structure 100, as shown in FIG. 1. In another embodiment, the annealing process also may be performed after the formation of the top electrode 102 in the condition that the top electrode 102 is not affected. The step S12 of this variant embodiment is the same as the aforementioned embodiment and will not be redundantly described.

The dielectric structures of the present invention are not limited by the aforementioned embodiments. Other different preferred embodiments are described below. To compare each embodiment conveniently and simplify the description, the identical components in each of the following embodiment are marked with identical symbols, and repeated parts will not be redundantly described.

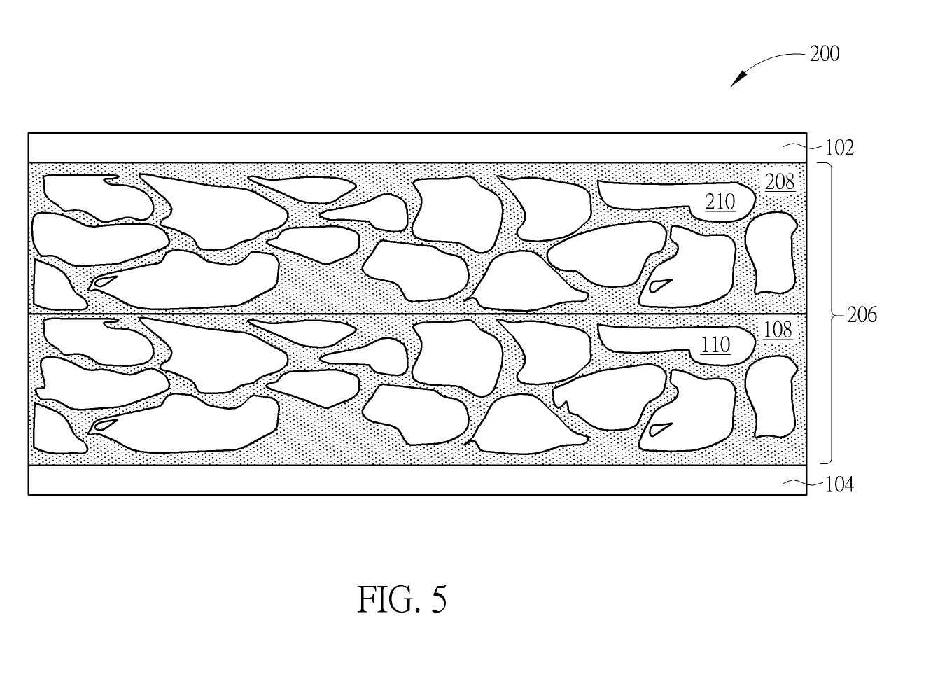

Please refer to FIG. 5, which is a schematic drawing of a cross-sectional view of the capacitor structure 200 according to a second embodiment of the present invention. As shown in FIG. 5, comparing with the first embodiment, the dielectric structure 206 of this embodiment may further include at least one second dielectric layer 208 and a plurality of second crystalline grains 210, and the second crystalline grains 210 are disposed in the second dielectric layer 208, in which the second dielectric layer 208 is stacked on the first dielectric layer 108. A dielectric constant of the second dielectric layer 208 is smaller than a dielectric constant of each second crystalline grain 210. The second dielectric layer 208 may include aluminum oxide, silicon nitride, zirconium oxide, hafnium oxide, lanthanum oxide, cerium oxide, barium titanate, gadolinium scandate, dysprosium scandate, lanthanum scandate, lanthanum aluminate, lanthanum lutetium oxide, tantalum oxide, titanium oxide or strontium titanate. The second dielectric layer 208 maybe composed of a high-K dielectric material the same as or different from the high-K dielectric material of the first dielectric layer 10. Each the second crystalline grain 210 may include zirconium oxide, hafnium oxide, lanthanum oxide, cerium oxide, barium titanate, gadolinium scandate, dysprosium scandate, lanthanum scandate, lanthanum aluminate, lanthanum lutetium oxide, tantalum oxide, titanium oxide or strontium titanate. Each second crystalline grain 210 may be composed of a high-K dielectric material the same as or different from the high-K dielectric material of the first crystalline grains 110. In this embodiment, the ratio of the volume of the second crystalline grains 210 to the volume the second dielectric layer 208 may be greater than 11/9 also. In other words, the dielectric structure 206 of this embodiment may be a multilayer structure, in which the crystalline grains may be disposed in each dielectric layer, the high-K dielectric materials of the different dielectric layers may be the same or different, and the crystalline grains disposed in the different dielectric layers maybe the same or different. For instance, when the crystalline grains in the different dielectric layers are composed of the same high-K dielectric material, the sizes of the crystalline grains disposed in the different dielectric layers may be different, and for example, they may be formed by adjusting the temperature, time or number of the annealing process. Further, the sizes of the crystalline grains disposed in the different dielectric layers may be controlled by adjusting the ratio of the high-K dielectric materials of the different dielectric layers.

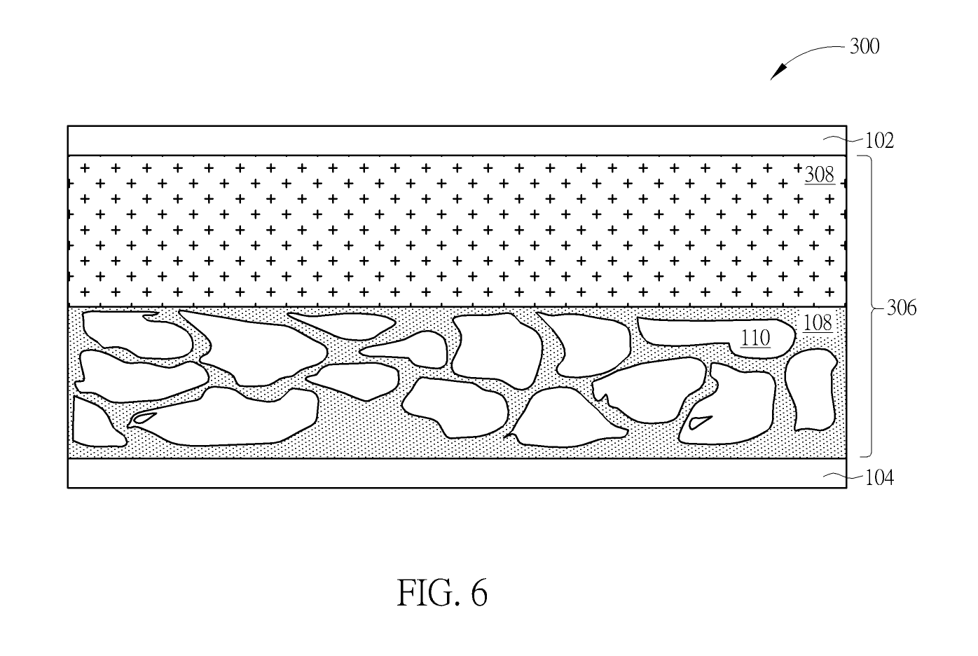

Please refer to FIG. 6, which is a schematic drawing of a cross-sectional view of the capacitor structure 300 according to a third embodiment of the present invention. As shown in FIG. 6, comparing with the first embodiment, the dielectric structure 306 of this embodiment further includes a third dielectric layer 308 stacked on the first dielectric layer 108, in which the third dielectric layer 308 includes a third high-K dielectric material, and a dielectric constant of the third high-K dielectric material is smaller than the dielectric constant of the second high-K dielectric material. For instance, the third high-K dielectric material may include amorphous aluminum oxide, so as to decrease the leakage current of the capacitor structure. In another embodiment, the third dielectric layer 308 may use other dielectric materials for providing other functions. Or, the dielectric structure 306 may include at least one dielectric layer composed of other dielectric materials. In another embodiment, the dielectric structure 306 may further include another first dielectric layer 108, and the third dielectric layer 308 disposed between two first dielectric layers 108, so as to form a stack of the first dielectric layer, the third dielectric layer 308 and the first dielectric layer 108 stacked sequentially between the bottom electrode 104 and the top electrode 102.

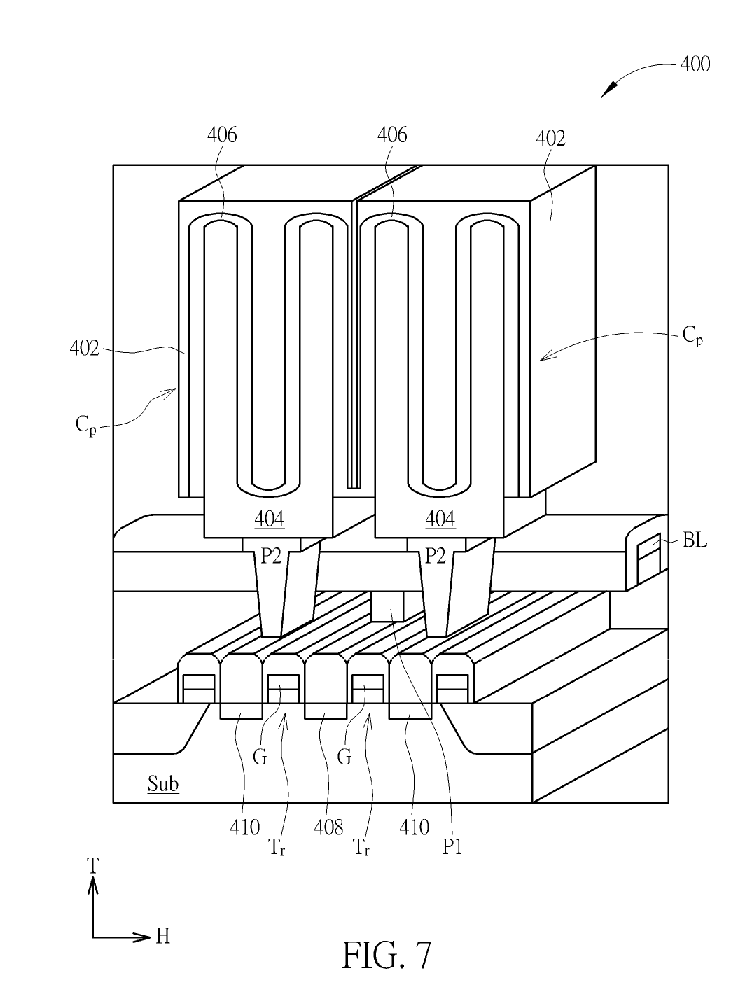

The capacitor structure according to any of the aforementioned embodiments of the present invention may be suitable for the memory structure, the memory structure detailed as follows takes DRAM as an example, but not limited thereto. Please refer to FIG. 7, which is a schematic drawing of a block diagram of the memory structure according to an embodiment of the present invention. As shown in FIG. 7, the memory structure 400 of this embodiment may include at least on transistor Tr and at least one capacitor structure Cp, in which the capacitor structure Cp may be a stack-type capacitor. The transistor Tr is disposed on a substrate Sub, and the capacitor structure Cp is disposed on the transistor Tr, in which a bottom electrode 404 of the capacitor structure Cp is electrically connected to a source of the transistor Tr. Also, a gate G of the transistor Tr is electrically connected to a word line (not shown in figure), and a drain of the transistor Tr is electrically connected to a bit line BL. Specifically, the memory structure 400 may include two transistors Tr and two capacitor structures Cp. The transistors Tr may share a same first doping region 408 disposed in the substrate Sub which is used as the drains of both the transistors Tr, and the first doping region 408 is electrically connected to the bit line BL by a contact plug P1. Each transistor Tr may further include a second doping region 410 respectively, and the second doping regions 410 serve as the sources of the transistors Tr respectively. The second doping regions 410 are disposed at two sides of the first doping region 408 respectively, and separated from the first doping region 408. The gate G of each transistor Tr is disposed between the corresponding second doping region 410 and the first doping region 408. Each second doping region 410 may be electrically connected to the bottom electrode 404 of the corresponding capacitor structure Cp by the corresponding contact plug respectively. The first doping region 408 and the second doping regions 410 may have the same conductive type and have the conductive type opposite to the substrate Sub, but not limited thereto. In another embodiment, the first doping region 408 and the second doping regions 410 may be disposed in a well region of the substrate Sub, and the conductive type of the first doping region 408 and the second doping regions 410 may be opposite to the conductive type of the well region. In each capacitor structure Cp of this embodiment, the bottom electrode 404 may have a U-shaped structure which notch is disposed upwardly. The dielectric structure 406 is formed on a bending top surface of the bottom electrode 404 uniformly, so as to increase the effective area of the capacitor structure Cp and raise the capacitance of the capacitor structure Cp in the condition that the size in the horizontal direction H does not be changed. The interior materials and the structure of the dielectric structure 406 of this embodiment may be suitable for the dielectric structure of any aforementioned embodiment, and will not be redundantly described. The top electrode 402 is formed on the dielectric structure 406. In another embodiment, two protrusion parts of the U-shaped structure of the bottom electrode 404 may have non-smooth surfaces, that is to say, the surfaces of the protrusion parts may be uneven surfaces, for example, the uneven surfaces are formed by the hemispherical grain (HSG) process, such that the surface area of the dielectric structure 406 formed uniformly on the bottom electrode 404 can be increased, thereby improving the capacitance of the capacitor structure Cp. In another embodiment, the capacitor structure Cp may be a trench-type capacitor, in which the capacitor structure Cp is disposed under the transistor Tr.

To summarize, in the manufacturing method of the dielectric structure of the present invention, the second amorphous grains can be crystallized effectively by performing the annealing process after forming the first amorphous grains and the second amorphous grains, thereby forming the crystal structure. Therefore, the dielectric constant of the amorphous second high-K dielectric material can be significantly increased to be the dielectric constant of the first crystalline grains so as to increase the dielectric constant of the whole dielectric structure. For this reason, the capacitance of the capacitor of the memory structure using the dielectric structure cannot be decreased in the condition of reducing the component area, and further, the capacitance of the capacitor can be increased even to increase the capacity of the stored charge.

Those skilled in the art will readily observe that numerous modifications and alterations of the device and method may be made while retaining the teachings of the invention. Accordingly, the above disclosure should be construed as limited only by the metes and bounds of the appended claims.

1. A dielectric structure, comprising:
a first dielectric layer comprising a first high-K dielectric material; and
a plurality of first crystalline grains disposed in the first dielectric layer, and each first crystalline grain comprising a second high-K dielectric material, wherein the first high-K dielectric material is different from the second high-K dielectric material, each first crystalline grain has a crystal structure, so that a dielectric constant of each first crystalline grain is greater than a dielectric constant of the first high-K dielectric material and the dielectric constant of each first crystalline grain is greater than 20.

2. The dielectric structure according to claim 1, wherein a particle size of each first crystalline grain is smaller than 100 nanometer (nm).

3. The dielectric structure according to claim 1, wherein the first crystalline grains are separated each other by the first dielectric layer.

4. The dielectric structure according to claim 1, wherein the second high-K dielectric material comprises zirconium oxide, hafnium oxide, lanthanum oxide, cerium oxide, barium titanate, gadolinium scandate, dysprosium scandate, lanthanum scandate, lanthanum aluminate, lanthanum lutetium oxide, tantalum oxide, titanium oxide or strontium titanate.

5. The dielectric structure according to claim 1, wherein the crystal structure of each first crystalline grain is cubic crystal structure, tetragonal crystal structure or monoclinic crystal structure.

6. The dielectric structure according to claim 1, wherein the dielectric constant of the first high-K dielectric material is greater than 20.

7. The dielectric structure according to claim 1, wherein the first high-K dielectric material comprises zirconium oxide, hafnium oxide, lanthanum oxide, cerium oxide, barium titanate, gadolinium scandate, dysprosium scandate, lanthanum scandate, lanthanum aluminate, lanthanum lutetium oxide, tantalum oxide, titanium oxide or strontium titanate.

8. The dielectric structure according to claim 1, wherein a ratio of a volume of the first crystalline grains to a volume of the first dielectric layer is greater than 11/9.

9. The dielectric structure according to claim 1, wherein the first high-K dielectric material and the second high-K dielectric material are immiscible at a temperature of 350° C. to 700° C.

10. The dielectric structure according to claim 1, further comprising a second dielectric layer and a plurality of second crystalline grains, and the second crystalline grains disposed in the second dielectric layer, wherein the second dielectric layer is stacked on the first dielectric layer.

11. The dielectric structure according to claim 1, further comprising a third dielectric layer stacked on the first dielectric layer, wherein the third dielectric layer comprises a third high-K dielectric material, and a dielectric constant of the third high-K dielectric material is smaller than the dielectric constant of each first crystalline grain.

12. The dielectric structure according to claim 11, wherein the third high-K dielectric material comprises amorphous aluminum oxide.

13. A memory structure, comprising:
a transistor disposed on a substrate;
a bottom electrode electrically connected to a source of the transistor;
a top electrode disposed on the bottom electrode; and
a dielectric structure disposed between the bottom electrode and the top electrode, and the dielectric structure comprising:
a first dielectric layer comprising the first high-K dielectric material; and
a plurality of first crystalline grains disposed in the first dielectric layer, and each first crystalline grain comprising a second high-K dielectric material, wherein the first high-K dielectric material is different from the second high-K dielectric material, each first crystalline grain has a crystal structure, so that a dielectric constant of each first crystalline grain is greater than a dielectric constant of the first high-K dielectric material and the dielectric constant of each first crystalline grain is greater than 20.

14. A manufacturing method of a dielectric structure, wherein the dielectric structure is formed on a bottom electrode, and the manufacturing method comprises:
forming an amorphous deposition layer on the bottom electrode, and the amorphous deposition layer comprising a first high-K dielectric material and a second high-K dielectric material, wherein the first high-K dielectric material and the second high-K dielectric material are mixed, and a dielectric constant of the second high-K dielectric material is greater than a dielectric constant of the first high-K dielectric material; and
performing an annealing process to the amorphous deposition layer, so as to segregate the first high-K dielectric material and form a dielectric layer and a plurality of crystalline grains, and the crystalline grains disposed in the dielectric layer, wherein the dielectric layer comprises the first high-K dielectric material, and each crystalline grain comprises the second high-K dielectric material.

15. The manufacturing method of the dielectric structure according to claim 14, wherein the dielectric constant of the second high-K dielectric material is greater than 20, and each the crystalline grain has a crystal structure, so that a dielectric constant of each crystalline grain is greater than a dielectric constant of the second high-K dielectric material.

16. The manufacturing method of the dielectric structure according to claim 14, wherein the crystalline grains are separated each other by the dielectric layer.

17. The manufacturing method of the dielectric structure according to claim 14, wherein the amorphous deposition layer comprises a plurality of first amorphous grains and a plurality of second amorphous grains, each first amorphous grain comprises the first high-K dielectric material, each second amorphous grain comprises the second high-K dielectric material, and forming the amorphous deposition layer comprises forming the first amorphous grains and the second amorphous grains mixed each other on the bottom electrode.

18. The manufacturing method of the dielectric structure according to claim 14, wherein the amorphous deposition layer comprises a plurality of first amorphous layers and a plurality of second amorphous layers, each first amorphous layer comprises the first high-K dielectric material, each the second amorphous layer comprises the second high-K dielectric material, and forming the amorphous deposition layer comprises alternately forming each first amorphous layer and each second amorphous layer on the bottom electrode.

19. The manufacturing method of the dielectric structure according to claim 14, wherein the first high-K dielectric material and the second high-K dielectric material are immiscible.

20. The manufacturing method of the dielectric structure according to claim 14, wherein a particle size of each crystalline grain is smaller than 100 nm.

21. The manufacturing method of the dielectric structure according to claim 14, wherein the second high-K dielectric material comprises zirconium oxide, hafnium oxide, lanthanum oxide, cerium oxide, barium titanate, gadolinium scandate, dysprosium scandate, lanthanum scandate, lanthanum aluminate, lanthanum lutetium oxide, tantalum oxide, titanium oxide or strontium titanate.

22. The manufacturing method of the dielectric structure according to claim 14, wherein the annealing process comprises crystallizing the second high-K dielectric material into cubic crystal structure, tetragonal crystal structure or monoclinic crystal structure.

23. The manufacturing method of the dielectric structure according to claim 14, wherein the dielectric constant of the first high-K dielectric material is greater than 20.

24. The manufacturing method of the dielectric structure according to claim 14, wherein the first high-K dielectric material comprises aluminum oxide, silicon nitride, zirconium oxide, hafnium oxide, lanthanum oxide, cerium oxide, barium titanate, gadolinium scandate, dysprosium scandate, lanthanum scandate, lanthanum aluminate, lanthanum lutetium oxide, tantalum oxide, titanium oxide or strontium titanate.

25. The manufacturing method of the dielectric structure according to claim 14, wherein a ratio of a volume of the crystalline grains to a volume of the dielectric layer is greater than 11/9.

26. The dielectric structure according to claim 1, wherein the first high-K dielectric material comprises aluminum oxide or silicon nitride.
